(19) United States
(12) Patent Application Publication
(10) Pub. No.: US 2026/0206298 A1
(43) Pub. Date: Jul. 16, 2026

(54) TRENCH POWER SEMICONDUCTOR DEVICE

(71) Applicant: Excelliance MOS Corporation, Hsinchu County (TW)

(72) Inventors: Chu-Kuang Liu, Hsinchu County (TW); Yun-Han Cheng, Hsinchu County (TW)

(73) Assignee: Excelliance MOS Corporation, Hsinchu County (TW)

(21) Appl. No.: 19/047,649

(22) Filed: Feb. 7, 2025

(30) Foreign Application Priority Data
Jan. 10, 2025 (TW) 114101189

(51) Int. Cl. H10D 84/83; H10D 12/00; H10D 12/01; H10D 30/01; H10D 30/60; H10D 62/13; H10D 64/23; H10D 64/27; H10D 84/01

(52) U.S. Cl. CPC H10D 84/8314; H10D 12/211; H10D 30/611; H10D 62/151; H10D 64/256; H10D 64/258; H10D 64/513; H10D 64/516; H10D 64/518; H10D 12/021; H10D 30/023; H10D 84/013; H10D 84/0144; H10D 84/0149

(57) ABSTRACT

A trench power semiconductor device includes a substrate, an epitaxial layer, a first gate structure, a second gate structure, a body region, a first source region, and a second source region. The epitaxial layer is on the substrate and has first trenches and second trenches alternatively arranged. The first gate structure is disposed within each first trench to form MCD elements. The second gate structure is disposed within each second trench to form MOS elements. The body region is formed in the epitaxial layer and between the first trenches and the second trenches. The first source region is formed in the body region at two sides of each first trench. The second source region is formed in the body region at two sides of each second trench. A bottom surface of the first source region is not lower than a bottom surface of the second source region.

### CROSS-REFERENCE TO RELATED APPLICATION

This application claims the priority benefit of Taiwan application serial no. 114101189, filed on Jan. 10, 2025. The entirety of the above-mentioned patent application is hereby incorporated by reference herein and made a part of this specification.

### BACKGROUND

### Technical Field

The disclosure relates to a semiconductor device, and in particular to a trench power semiconductor device.

### Related Art

In power semiconductor devices, to avoid simultaneous conduction of high-side and low-side transistor switches, which may cause large currents to flow through and potentially damage the device, a time interval, referred to as dead time, is generally set in the circuit design when both the high-side and low-side transistors are turned off. During this period, the load current flows through the body diode of the low-side transistor, resulting in additional energy loss. How to reduce this energy loss is a problem that needs to be improved currently.

### SUMMARY

The disclosure provides a trench power semiconductor device which may reduce energy loss and have good reliability.

A trench power semiconductor device of the disclosure includes a substrate, an epitaxial layer, a first gate structure, a second gate structure, a body region, a first source region, and a second source region. The epitaxial layer is located on the substrate, where the epitaxial layer has multiple first trenches and multiple second trenches alternately arranged. The first gate structure is disposed within each of the first trenches to form a MOS controlled diode (MCD) element. The second gate structure is disposed within each of the second trenches to form a MOS element. The body region is formed in the epitaxial layer and located between the first trenches and the second trenches. The first source region is formed in the body region at two sides of each of the first trenches. The second source region is formed in the body region at two sides of each of the second trenches, and connected to the first source region. A bottom surface of the first source region is not lower than a bottom surface of the second source region.

In an embodiment of the disclosure, the first gate structure includes a first top gate and a first gate dielectric layer. The first top gate is located within the first trench. The first gate dielectric layer is located between the first top gate and the body region. The second gate structure includes a second top gate and a second gate dielectric layer. The second top gate is located within the second trench. The second gate dielectric layer is located between the second top gate and the body region. A thickness of the first gate dielectric layer is less than a thickness of the second gate dielectric layer.

In an embodiment of the disclosure, a ratio of the thickness of the first gate dielectric layer to the thickness of the second gate dielectric layer is between 0.04 and 0.14.

In an embodiment of the disclosure, the first gate dielectric layer further extends to a top surface of the epitaxial layer above the first source region, and the second gate dielectric layer further extends to the top surface of the epitaxial layer above the second source region.

In an embodiment of the disclosure, a channel length of the MCD element is greater than or equal to a channel length of the MOS element.

In an embodiment of the disclosure, the body region includes a first portion and a second portion. The first portion is close to the first trenches and overlaps with the first source region in a vertical direction. The second portion is close to the second trenches and overlaps with the second source region in the vertical direction. A bottom surface of the second portion is higher than a bottom surface of the first portion.

In an embodiment of the disclosure, the first gate structure further includes a first bottom gate, a first thick oxide layer, and a first inter-gate dielectric layer. The first bottom gate is located below the first top gate. The first thick oxide layer is located between the first bottom gate and the epitaxial layer. The first inter-gate dielectric layer is located between the first top gate and the first bottom gate.

In an embodiment of the disclosure, the first top gate is electrically connected to the first source region and the second source region.

In an embodiment of the disclosure, the trench power semiconductor device further includes a source metal layer and a gate metal layer. The source metal layer is disposed on the epitaxial layer and electrically connected to the first top gate, the first source region, and the second source region. The gate metal layer is disposed on the epitaxial layer and electrically connected to the second top gate.

In an embodiment of the disclosure, the trench power semiconductor device further includes a source contact window, which connects the source metal layer to the first top gate, the first source region, or the second source region.

Based on the above, the trench power semiconductor device of the disclosure includes the MCD element connected in parallel between the source and drain of the MOS element, which may effectively reduce the energy loss of the trench power semiconductor device during the dead time and have improved reliability. Furthermore, the first source region and the second source region of the disclosure are formed in the body region through different ion implantation processes, so that the implantation depth of the first source region and the second source region may be individually adjusted to accommodate the MCD element and the MOS element, thereby enhancing flexibility in application.

### BRIEF DESCRIPTION OF THE DRAWINGS

FIG. 1 to FIG. 12 are schematic cross-sectional views of a process of manufacturing a trench semiconductor device according to an embodiment of the disclosure.

### DESCRIPTION OF THE EMBODIMENTS

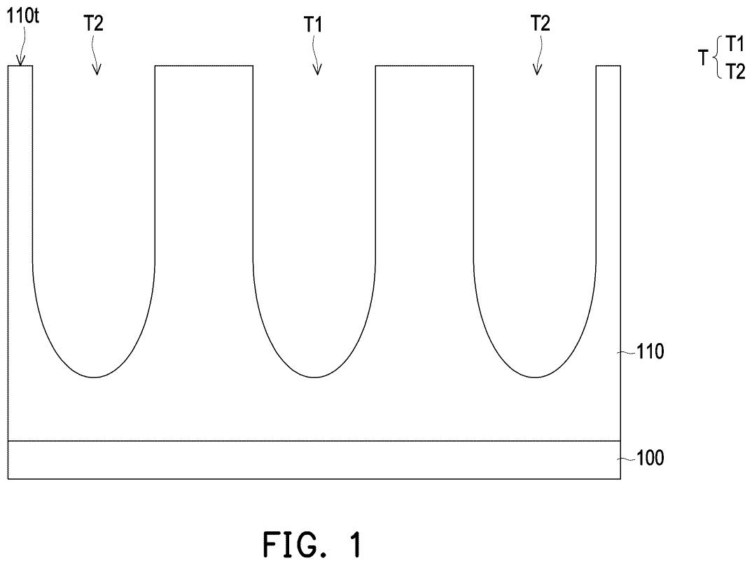

FIG. 1 to FIG. 12 are schematic cross-sectional views of a process of manufacturing a trench semiconductor device according to an embodiment of the disclosure.

Referring to FIG. 1, an epitaxial layer 110 is formed on a substrate 100, and then multiple trenches T are formed in the epitaxial layer 110. A method of forming the trenches T may include, for example, first forming a mask layer (not shown, for example, a hard mask layer and/or a photoresist layer) on a top surface 110t of the epitaxial layer 110, then using a photolithography and etching process to expose the predetermined top surface 110t of the epitaxial layer 110 where the trenches T are to be formed, and then etching the epitaxial layer 110 (for example, anisotropic etching) by using the mask layer as an etching mask to form the trenches T. The mask layer is later removed.

In some embodiments, the substrate 100 may be a semiconductor substrate, such as a silicon substrate or other suitable semiconductor substrates. In some embodiments, the substrate 100 and the epitaxial layer 110 may have a dopant of a first conductive type, respectively. The first conductive type may be, for example, an N-type. The N-type dopant may include phosphorus, arsenic, antimony, or the like. In some embodiments, the substrate 100 may be an N+ substrate, and the epitaxial layer 110 may be an N− epitaxial layer.

In some embodiments, the trenches T may include multiple first trenches T1 and multiple second trenches T2 alternately arranged, and the first trenches T1 and the second trenches T2 are disposed adjacently. In this embodiment, the first trenches T1 are configured to form MOS controlled diode (MCD) elements, and the second trenches T2 are configured to form MOS elements. FIG. 1 illustratively shows one first trench T1 and two second trenches T2, but is not intended to limit the disclosure. The number of first trenches T1 and second trenches T2 may be adjusted and disposed according to actual requirements.

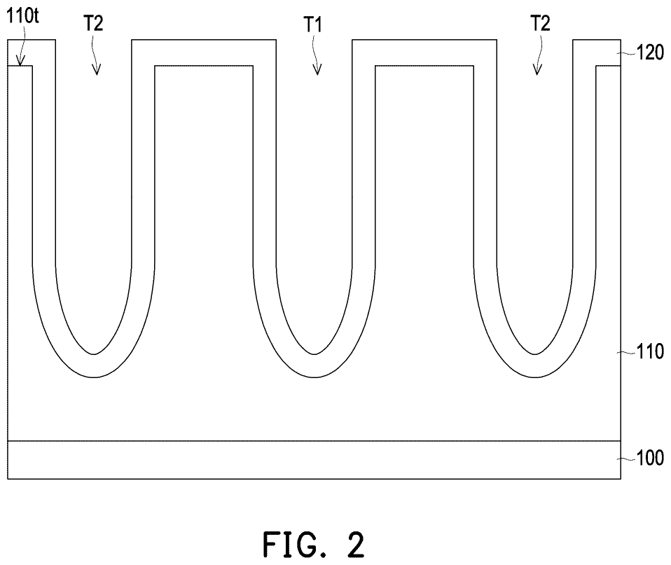

Referring to FIG. 2, an oxide layer 120 is formed on the epitaxial layer 110. For example, the oxide layer 120 may be conformally deposited on the surfaces of the trenches T and the top surface 110t of the epitaxial layer 110 through thermal oxidation or deposition process (such as chemical vapor deposition process and thermal oxidation plus chemical deposition process). In some embodiments, the oxide layer 120 may include silicon oxide.

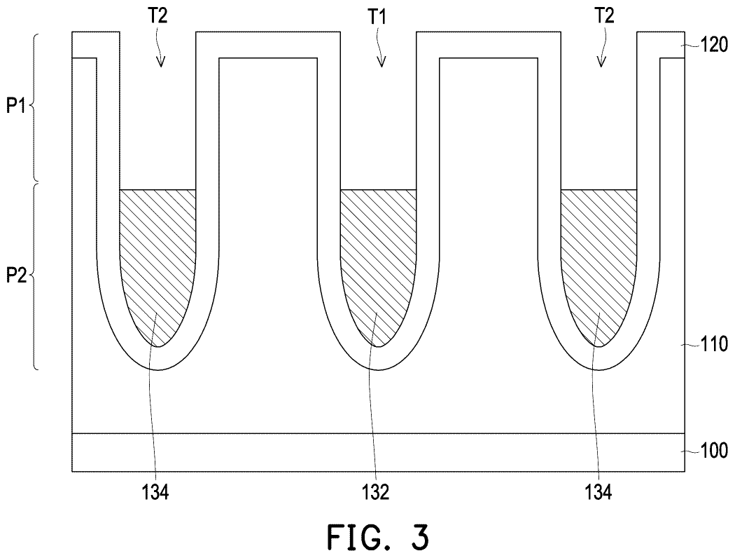

Referring to FIG. 3, a first bottom gate 132 is formed in each first trench T1, and a second bottom gate 134 is formed in each second trench T2. For example, a conductive material (not shown) may be first deposited above the entire oxide layer 120, and then may be etched back, so that the conductive material within and above an upper portion P1 of the first trenches T1 and second trenches T2 is removed. The conductive material remaining in a lower portion P2 of the first trenches T1 forms the first bottom gates 132, and the conductive material remaining in the lower portion P2 of the second trenches T2 forms the second bottom gates 134. In some embodiments, the conductive material or a material of the first bottom gates 132 or the second bottom gates 134 may include polysilicon or other suitable conductive materials.

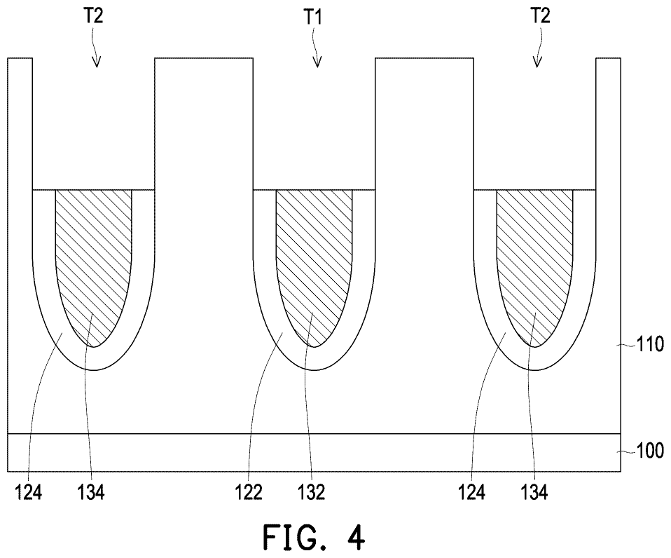

Referring to FIG. 4, the exposed oxide layer 120 in FIG. 3 is removed to form a first thick oxide layer 122 in the first trench T1 and a second thick oxide layer 124 in the second trench T2.

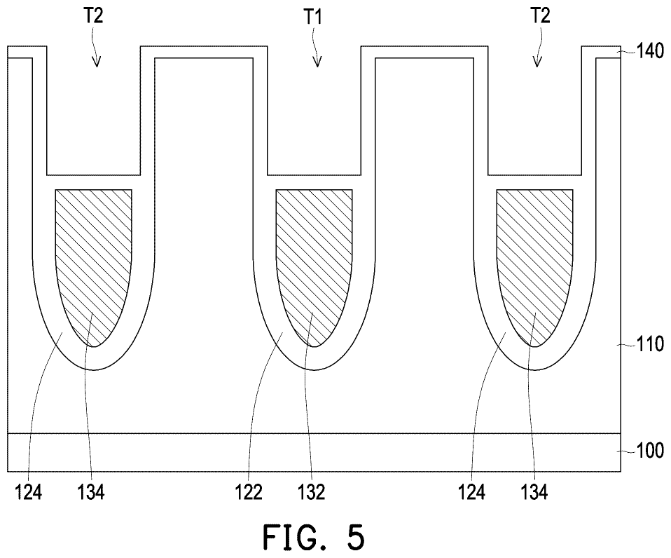

Referring to FIG. 5, a dielectric layer 140 is conformally formed on the exposed surfaces of the first bottom gates 132, the second bottom gates 134, and the epitaxial layer 110. In some embodiments, the dielectric layer 140 may be formed through chemical vapor deposition process, thermal oxidation process, or other suitable deposition processes. In some embodiments, the dielectric layer 140 may include silicon oxide or other suitable dielectric materials.

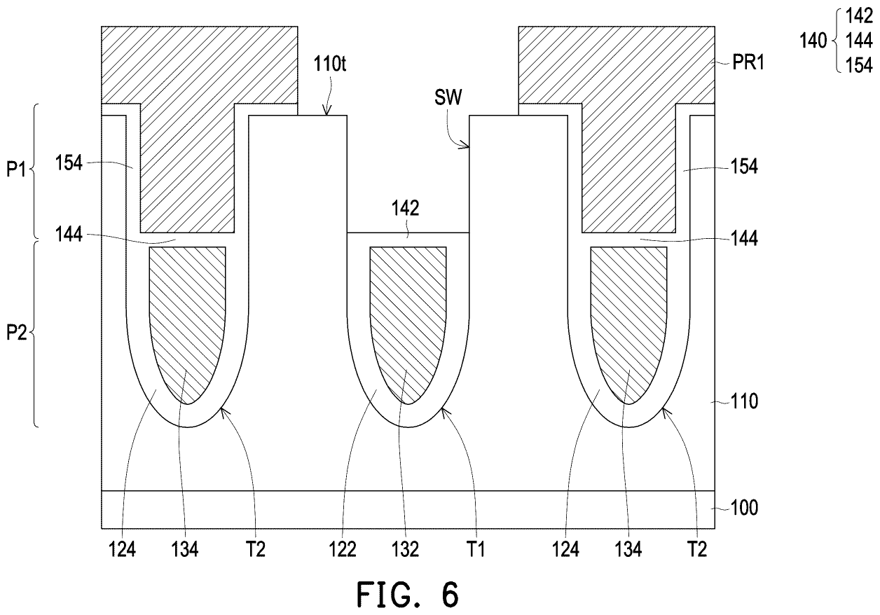

Referring to FIG. 6, a portion of the dielectric layer 140 in the first trench T1 is removed to expose a sidewall SW of the upper portion P1 of the first trench T1. For example, a patterned photoresist layer PR1 may be first formed above the epitaxial layer 110 to cover the second trench T2 and the portion of the dielectric layer 140 on the epitaxial layer 110 surrounding the second trench T2, while exposing the first trench T1 and the portion of the dielectric layer 140 on the epitaxial layer 110 surrounding the first trench T1. Afterwards, through an etching process, the dielectric layer 140 on the sidewall SW of the first trench T1 and on the epitaxial layer 110 surrounding the first trench T1 that is not covered by the patterned photoresist layer PR1 may be removed, thereby exposing the sidewall of the upper portion P1 of the first trench T1 and a portion of the top surface 110t of the epitaxial layer 110.

In some embodiments, the dielectric layer 140 on the first bottom gate 132 may be partially removed during the etching process, but still covers the first bottom gate 132. The dielectric layer 140 with a portion covering the first bottom gate 132 may compose a first inter-gate dielectric layer 142. Furthermore, the dielectric layer 140 with a portion covering the second bottom gate 134 may compose a second inter-gate dielectric layer 144, and a portion of the dielectric layer 140 on the sidewall of the upper portion P1 of the second trench T2 and extending to the top surface 110t of the epitaxial layer 110 may compose a second gate dielectric layer 154.

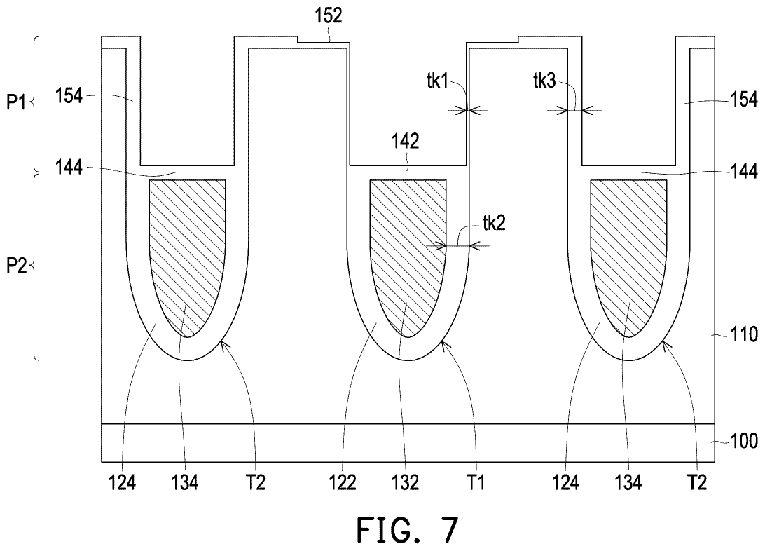

Referring to FIG. 7, after the patterned photoresist layer PR1 shown in FIG. 6 is removed, a thermal oxidation process is performed on the epitaxial layer 110 to form a thin oxide layer, namely the first gate dielectric layer 152, on the exposed surface of the epitaxial layer 110. A thickness tk1 of the first gate dielectric layer 152 is smaller than a thickness tk3 of the second gate dielectric layer 154, and also smaller than a thickness tk2 of the first thick oxide layer 122. In some embodiments, a material of the first gate dielectric layer 152 may include silicon oxide.

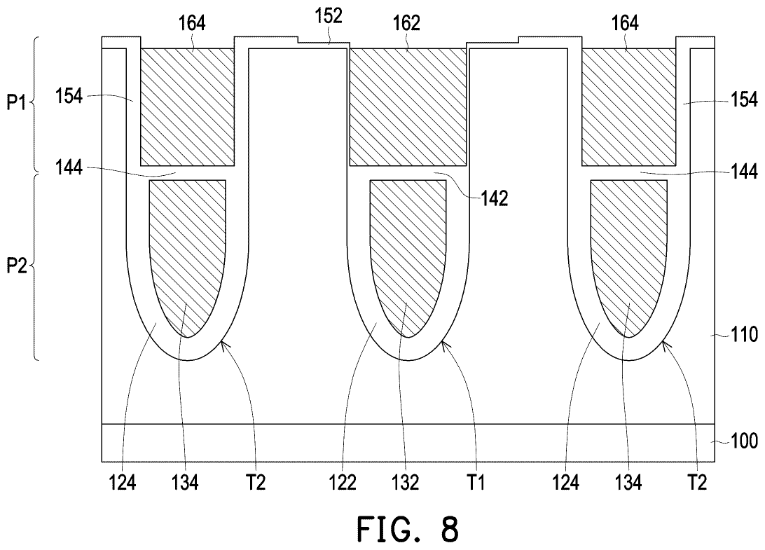

Referring to FIG. 8, a first top gate 162 is formed in the upper portion P1 of the first trench T1, and a second top gate 164 is formed in the upper portion P1 of the second trench T2. For example, a conductive material (not shown) may be deposited in the first trench T1, the second trench T2, and above the top surface of the epitaxial layer 110, and then the excess conductive material formed above the top surface of the epitaxial layer 110 may be removed (for example, through a planarization process or other suitable process), so that the conductive material remaining in the upper portion P1 of the first trench T1 forms the first top gate 162, and the conductive material remaining in the upper portion P1 of the second trench T2 forms the second top gate 164. In some embodiments, the conductive material or a material of the first top gate 162 or the second top gate 164 may include polysilicon or other suitable conductive materials.

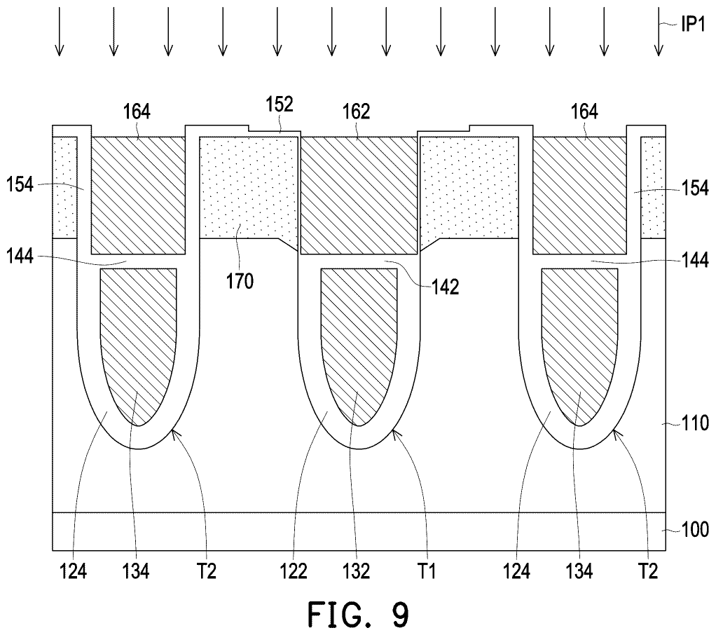

Referring to FIG. 9, a body region 170 is formed in the epitaxial layer 110. For example, a dopant of a second conductive type, such as a P-type, may be implanted from the top surface 110t of the epitaxial layer 110 through an ion implantation process IP1 to form a P-type body region 170 between the first trench T1 and the second trench T2. The P-type dopants may include, for example, boron, aluminum, gallium, or the like.

In some embodiments, a depth of the body region 170 may not exceed the top surfaces of the first inter-gate dielectric layer 142 and the second inter-gate dielectric layer 144. Because the thickness tk1 (shown in FIG. 7) of the first gate dielectric layer 152 is smaller than the thickness tk3 (shown in FIG. 7) of the second gate dielectric layer 154, a bottom of the body region 170 close to the first trench T1 may be lower than a bottom of the body region 170 close to the second trench T2.

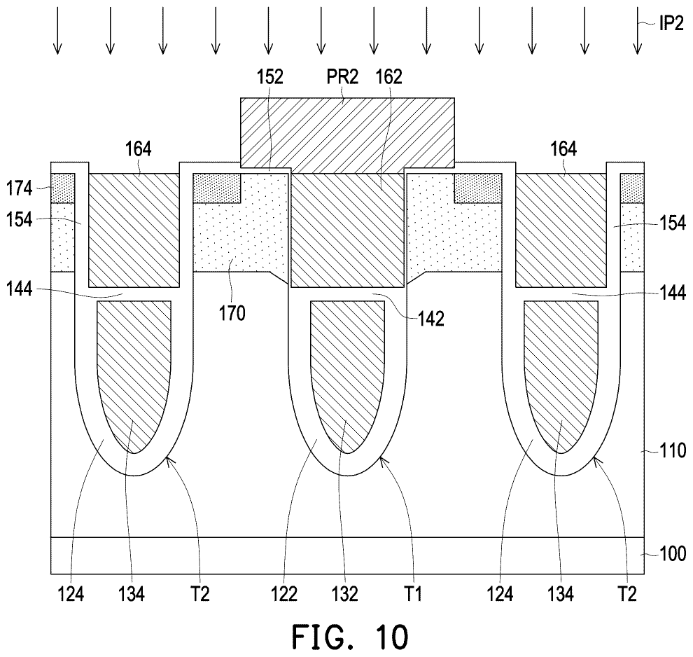

Referring to FIG. 10, second source regions 174 are formed in the body region 170 at two sides of the second trench T2. For example, a patterned photoresist layer PR2 may be formed on the epitaxial layer 110 by using a first mask (not shown) to cover the first trench T 1 and portions of the first gate dielectric layer 152 on the top surface 110t of the epitaxial layer 110 at two sides of the first trench T1 and expose the second trench T2 and portions of the second gate dielectric layer 154 on the top surface 110t of the epitaxial layer 110 at two sides of the second trench T2. Afterwards, the dopant of the first conductive type, such as the N-type, may be implanted from the top surface 110t of the epitaxial layer 110 that is not covered by the patterned photoresist layer PR2 through an ion implantation process IP2 to form N+ type second source regions 174 in the body region 170 at two sides of the second trench T2 that are not covered by the patterned photoresist layer PR2.

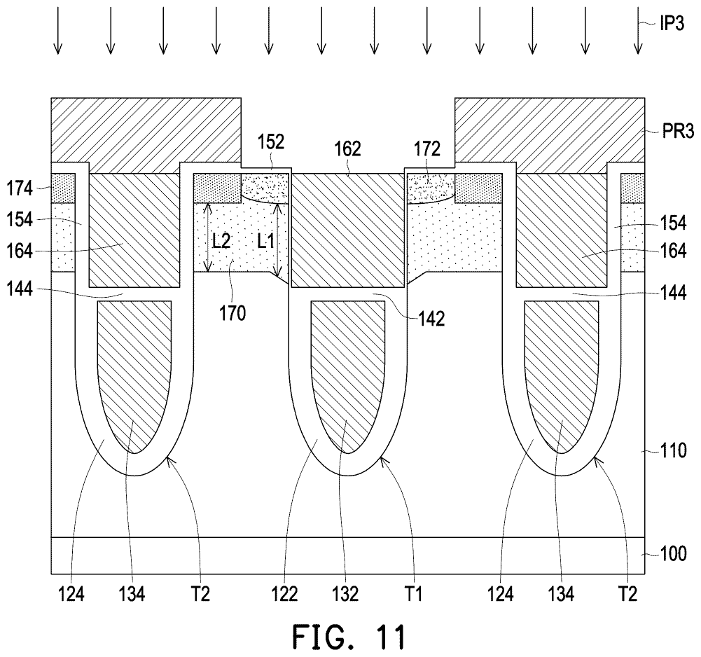

Referring to FIG. 11, after the patterned photoresist layer PR2 shown in FIG. 10 is removed, first source regions 172 are formed in the body region 170 at two sides of the first trench T1. For example, a patterned photoresist layer PR3 may be formed on the epitaxial layer 110 by using a second mask (not shown) to cover the second trench T2 and portions of the second gate dielectric layer 154 on the top surface 110t of the epitaxial layer 110 on both sides of the second trench T2 and expose the first trench T1 and portions of the first gate dielectric layer 152 on the top surface 110t of the epitaxial layer 110 at two sides of the first trench T1. Afterwards, the dopant of the first conductive type, such as the N-type, may be implanted from the top surface 110t of the epitaxial layer 110 that is not covered by the patterned photoresist layer PR3 through an ion implantation process IP3 to form N+ type first source regions 172 in the body region 170 at two sides of the first trench T1 that are not covered by the patterned photoresist layer PR3.

Since the first source region 172 and the second source region 174 are formed through different ion implantation processes, the implantation depths of the first source region 172 and the second source region 174 may be individually adjusted to meet the requirements of different elements (such as MCD elements and MOS elements), thereby allowing adjustment of the channel lengths (such as channel lengths L1 and L2) of the elements to enhance flexibility in application. Moreover, compared to forming the first source region 172 and the second source region 174 by using the same ion implantation process, forming the first source region 172 and the second source region 174 through different ion implantation processes may reduce the risk of channel punch through that may be caused by the first source region 172 having an excessive implantation depth due to the thinner first gate dielectric layer 152.

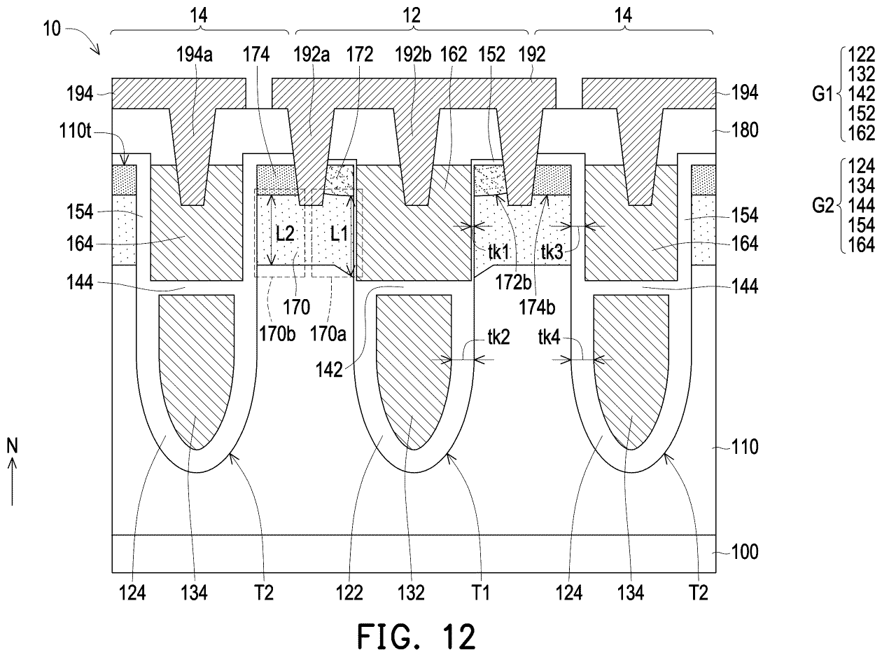

Referring to FIG. 12, after the patterned photoresist layer PR3 shown in FIG. 11 is removed, an insulating layer 180 is formed on the epitaxial layer 110 to cover the first trench T1 and the second trench T2. Afterwards, source contact windows 192a and 192b and a gate contact window 194a are formed in the insulating layer 180. The source contact window 192a penetrates through the insulating layer 180 and the underlying first gate dielectric layer 152 and/or second gate dielectric layer 154, the first source region 172 and/or second source region 174, and a portion of the body region 170. The source contact window 192b penetrates through the insulating layer 180 and a portion of the underlying first top gate 162. The gate contact window 194a penetrates through the insulating layer 180 and a portion of the underlying second top gate 164. Subsequently, a source metal layer 192 and a gate metal layer 194 are formed on the insulating layer 180, where the source metal layer 192 is physically and electrically connected to the source contact windows 192a and 192b, and the gate metal layer 194 is physically and electrically connected to the gate contact window 194a.

In some embodiments, a method of forming the source contact windows 192a and 192b and the gate contact window 194a is as follows. For example, after the formation of the insulating layer 180, a patterned photoresist layer (not shown) is formed on the insulating layer 180, exposing predetermined areas for forming the source contact windows 192a and 192b and the gate contact window 194a. Then, etching is performed to form a first opening (not shown) penetrating through the insulating layer 180, the first gate dielectric layer 152 and/or the second gate dielectric layer 154, the first source region 172 and/or the second source region 174, and the portion of the body region 170, a second opening (not shown) penetrating through the insulating layer 180 and a portion of the first top gate 162, and a third opening (not shown) penetrating through the insulating layer 180 and a portion of the second top gate 164. Afterwards, a metal material is filled into the first opening, the second opening, and the third opening to form the source contact windows 192a and 192b and the gate contact window 194a. In some embodiments, after the first opening is formed and before the aforementioned conductive material is filled, the dopant of the second conductive type (that is, the P-type dopant) may be implanted from the first opening by ion implantation to pre-form a P+ region (not shown) in a region at a bottom of the source contact window 192a.

Based on the above, manufacturing the trench power semiconductor device 10 may be substantially completed.

Therefore, the trench power semiconductor device 10 in an embodiment of the disclosure, as shown in FIG. 12, includes a substrate 100, an epitaxial layer 110, a first gate structure G1, a second gate structure G2, a body region 170, a first source region 172, and a second source region 174. The epitaxial layer 110 is located on the substrate 100 and have multiple first trenches T1 and multiple second trenches T2 alternately arranged. The first gate structure G1 is disposed in each of the first trenches T1 to form an MCD element 12. The second gate structure G2 is disposed in each of the second trenches T2 to form a MOS element 14. The first source region 172 is formed in the body region 170 at two sides of the first trench T1. The second source region 174 is formed in the body region 170 at two sides of the second trench T2 and connected to the first source region 172. In some embodiments, a source of the MOS element 14 is composed by the second source region 174, while a drain of the MOS element 14 is composed by the substrate 100. An anode of the MCD element 12 is composed by the body region 170, the first source region 172, and the first gate structure G1, while a cathode of the MCD element 12 is composed by the substrate 100. Since the trench power semiconductor device 10 includes the MCD element 12 connected in parallel between the source and drain of the MOS element 14, and the MCD element 12 has a low forward voltage drop and reverse leakage current, which may effectively reduce the energy loss of the trench power semiconductor device 10 during the dead time period and have improved reliability.

In some embodiments, the body region 170 includes a first portion 170a and a second portion 170b. The first portion 170a is close to the first trenches T1 and overlaps with the first source region 172 in a vertical direction N, while the second portion 170b is close to the second trenches T2 and overlaps with the second source region 174 in the vertical direction N. A bottom surface of the second portion 170b is higher than a bottom surface of the first portion 170a. Here, the vertical direction N refers to a direction perpendicular to a top surface of the substrate 100.

In some embodiments, a channel of the MCD element 12 is formed in the first portion 170a of the body region 170, and a channel of the MOS element 14 is formed in the second portion 170b of the body region 170.

Since the first source region 172 and the second source region 174 are formed through different ion implantation processes, such as the ion implantation process IP2 in FIG. 10 and the ion implantation process IP3 in FIG. 11, it is possible to precisely control the bottom surface 172b of the formed first source region 172 to be not lower than the bottom surface 174b of the second source region 174. In other words, compared to all source regions formed from the previous ion implantation process, the bottom surface 172b of the first source region 172 is not deeper than the bottom surface 174b of the second source region 174 due to the thinner first gate dielectric layer 152, thereby avoiding the risk of channel punch through in the MCD element. In some embodiments, the bottom surface 172b of the first source region 172 may be substantially flush with the bottom surface 174b of the second source region 174. Alternatively, in some embodiments, the bottom surface 172b of the first source region 172 may be higher than the bottom surface 174b of the second source region 174.

In some embodiments, a channel length L1 of the MCD element 12 may be greater than or equal to a channel length L2 of the MOS element 14.

In some embodiments, the first gate structure G1 may include a first thick oxide layer 122, a first bottom gate 132, a first inter-gate dielectric layer 142, a first gate dielectric layer 152, and a first top gate 162. The first top gate 162 is located within the first trench T1. The first gate dielectric layer 152 is located between the first top gate 162 and the body region 170. The first bottom gate 132 is located within the first trench T1 and beneath the first top gate 162. The first thick oxide layer 122 is located between the first bottom gate 132 and the epitaxial layer 110. The first inter-gate dielectric layer 142 is located between the first top gate 162 and the first bottom gate 132.

In some embodiments, the first bottom gate 132 may be at the same electrical potential as the first top gate 162, for example, both of which may be coupled to the source potential.

In some embodiments, the second gate structure G2 may include a second thick oxide layer 124, a second bottom gate 134, a second inter-gate dielectric layer 144, a second gate dielectric layer 154, and a second top gate 164. The second top gate 164 is located within the second trench T2. The second gate dielectric layer 154 is located between the second top gate 164 and the body region 170. The second bottom gate 134 is located within the second trench T2 and beneath the second top gate 164. The second thick oxide layer 124 is located between the second bottom gate 134 and the epitaxial layer 110. The second inter-gate dielectric layer 144 is located between the second top gate 164 and the second bottom gate 134.

In some embodiments, the second bottom gate 134 and the second top gate 164 are not at the same electrical potential. The second top gate 164 is configured for channel formation in the MOS element 14, while the second bottom gate 134 is coupled to the source potential to provide charge balance for the epitaxial layer 110.

In some embodiments, the thickness tk1 of the first gate dielectric layer 152 is smaller than the thickness tk3 of the second gate dielectric layer 154, in order to reduce the on-state voltage of the MCD element 12. In some embodiments, a ratio of the thickness tk1 of the first gate dielectric layer 152 to the thickness tk3 of the second gate dielectric layer 154 (that is, tk1/tk3) is between 0.04 and 0.14.

In some embodiments, the thickness tk2 of the first thick oxide layer 122 is greater than the thickness tk1 of the first gate dielectric layer 152. A thickness tk4 of the second thick oxide layer 124 is greater than the thickness tk3 of the second gate dielectric layer 154.

In some embodiments, the first gate dielectric layer 152 further extends to the top surface 110t of the epitaxial layer 110 above the first source region 172, to cover the first source region 172, and the second gate dielectric layer 154 further extends to the top surface 110t of the epitaxial layer 110 above the second source region 174, to cover the second source region 174.

In some embodiments, the first gate dielectric layer 152 may be connected to the second gate dielectric layer 154 on the top surface 110t of the epitaxial layer 110 (as shown in FIG. 11).

In some embodiments, the trench power semiconductor device 10 further includes a source metal layer 192 and a gate metal layer 194. The source metal layer 192 is disposed on the epitaxial layer 110 and electrically connected to the first top gate 162, the first source region 172, and the second source region 174. In other words, the first top gate 162 may be electrically connected to the first source region 172 and the second source region 174 through the source metal layer 192. The gate metal layer 194 is disposed on the epitaxial layer 110 and electrically connected to the second top gate 164.

In some embodiments, the trench power semiconductor device 10 further includes an insulating layer 180, source contact windows 192a and 192b, and a gate contact window 194a. The insulating layer 180 is disposed between the source metal layer 192 and the gate metal layer 194 and the epitaxial layer 110. The source contact windows 192a and 192b connect the source metal layer 192 to the first top gate 162, the first source region 172, or the second source region 174. The gate contact window 194a connects the gate metal layer 194 to the second top gate 164.

In some embodiments, the source contact window 192a penetrates through the insulating layer 180, the first gate dielectric layer 152 and/or the second gate dielectric layer 154, the first source region 172 and/or the second source region 174, and the portion of the body region 170, to make the first source region 172 and/or the second source region 174 be electrically connected to the source metal layer 192. For example, the source contact window 192a may penetrate through the first gate dielectric layer 152 and the first source region 172 without penetrating through the second gate dielectric layer 154 and the second source region 174, or the source contact window 192a may penetrate through the second gate dielectric layer 154 and the second source region 174 without penetrating through the first gate dielectric layer 152 and the first source region 172, or the source contact window 192a may penetrate from a connection point of the first gate dielectric layer 152 and the second gate dielectric layer 154, thereby simultaneously penetrating through the first gate dielectric layer 152, the second gate dielectric layer 154, the first source region 172, and the second source region 174.

In some embodiments, the source contact window 192b penetrates through the insulating layer 180 and the portion of the first top gate 162, to make the first top gate 162 be electrically connected to the source metal layer 192.

In some embodiments, the gate contact window 194a penetrates through the insulating layer 180 and the portion of the second top gate 164, to make the second top gate 164 be electrically connected to the gate metal layer 194.

In summary, the trench power semiconductor device of the disclosure includes the MCD element connected in parallel between the source and drain of the MOS element, which may effectively reduce the energy loss of the trench power semiconductor device during the dead time and have improved reliability. Furthermore, the first source region and the second source region of the disclosure are formed in the body region through different ion implantation processes, so that the implantation depths of the first source region and the second source region may be individually adjusted to accommodate the MCD element and the MOS element, thereby enhancing flexibility in application.

What is claimed is:

1. A trench power semiconductor device, comprising:
a substrate;
an epitaxial layer, located on the substrate, wherein the epitaxial layer has a plurality of first trenches and a plurality of second trenches alternately arranged;
a first gate structure, disposed within each of the plurality of first trenches, to form a MOS controlled diode (MCD) element;
a second gate structure, disposed within each of the plurality of second trenches, to form a MOS element;
a body region, formed in the epitaxial layer and located between the plurality of first trenches and the plurality of second trenches;
a first source region, formed in the body region at two sides of each of the plurality of first trenches; and
a second source region, formed in the body region at two sides of each of the plurality of second trenches, and connected to the first source region,
wherein a bottom surface of the first source region is not lower than a bottom surface of the second source region.

2. The trench power semiconductor device according to claim 1, wherein
the first gate structure comprises:
a first top gate, located within the first trench; and
a first gate dielectric layer, located between the first top gate and the body region, and
the second gate structure comprises:
a second top gate, located within the second trench; and
a second gate dielectric layer, located between the second top gate and the body region,
wherein a thickness of the first gate dielectric layer is less than a thickness of the second gate dielectric layer.

3. The trench power semiconductor device according to claim 2, wherein a ratio of the thickness of the first gate dielectric layer to the thickness of the second gate dielectric layer is between 0.04 and 0.14.

4. The trench power semiconductor device according to claim 2, wherein the first gate dielectric layer further extends to a top surface of the epitaxial layer above the first source region, and the second gate dielectric layer further extends to the top surface of the epitaxial layer above the second source region.

5. The trench power semiconductor device according to claim 1, wherein a channel length of the MCD element is greater than or equal to a channel length of the MOS element.

6. The trench power semiconductor device according to claim 1, wherein the body region comprises:
a first portion, being close to the plurality of first trenches and overlapping with the first source region in a vertical direction; and
a second portion, being close to the plurality of second trenches and overlapping with the second source region in the vertical direction,
wherein a bottom surface of the second portion is higher than a bottom surface of the first portion.

7. The trench power semiconductor device according to claim 2, wherein the first gate structure further comprises:
a first bottom gate, located below the first top gate;
a first thick oxide layer, located between the first bottom gate and the epitaxial layer; and
a first inter-gate dielectric layer, located between the first top gate and the first bottom gate.

8. The trench power semiconductor device according to claim 2, wherein the first top gate is electrically connected to the first source region and the second source region.

9. The trench power semiconductor device according to claim 2, further comprising:
a source metal layer, disposed on the epitaxial layer and electrically connected to the first top gate, the first source region, and the second source region; and
a gate metal layer, disposed on the epitaxial layer and electrically connected to the second top gate.

10. The trench power semiconductor device according to claim 9, further comprising:
a source contact window, connecting the source metal layer to the first top gate, the first source region, or the second source region.
